(19) United States
(12) Patent Application Publication
(10) Pub. No.: US 2024/0014297 A1
(43) Pub. Date: Jan. 11, 2024

(54) SEMICONDUCTOR DEVICE

(71) Applicant: Murata Manufacturing Co., Ltd., Kyoto-fu (JP)

(72) Inventors: Shaojun MA, Nagaokakyo-shi (JP); Yasunari UMEMOTO, Nagaokakyo-shi (JP); Shigeki KOYA, Nagaokakyo-shi (JP)

(73) Assignee: Murata Manufacturing Co., Ltd., Kyoto-fu (JP)

(21) Appl. No.: 18/474,102

(22) Filed: Sep. 25, 2023

Related U.S. Application Data
(63) Continuation of application No. PCT/JP2022/010653, filed on Mar. 10, 2022.

(30) Foreign Application Priority Data
Mar. 26, 2021 (JP) 2021-053562

(51) Int. Cl. H01L 29/737; H01L 29/06; H01L 29/417

(52) U.S. Cl. CPC H01L 29/737; H01L 29/0603; H01L 29/41708

(57) ABSTRACT

A semiconductor device includes an emitter electrode above an emitter layer of a bipolar transistor. An interlayer insulating film is on the emitter electrode. An emitter contact hole is in the interlayer insulating film and is surrounded by the emitter electrode when viewed in plan view. An emitter wire is on the interlayer insulating film. The emitter wire is coupled to the emitter electrode through the emitter contact hole. When viewed in plan view, the emitter electrode and the emitter contact hole are elongated in one direction. The length of the emitter contact hole is 85% or less of the length of the emitter electrode. Of two side ends of the emitter electrode, the distance from each side end to the emitter contact hole is 5% or more of the length of the emitter electrode. This configuration further enhances the temperature uniformity in the bipolar transistor in operation.

### CROSS-REFERENCE TO RELATED APPLICATIONS

This application claims benefit of priority to International Patent Application No. PCT/JP2022/010653, filed Mar. 10, 2022, and to Japanese Patent Application No. 2021-053562, filed Mar. 26, 2021, the entire contents of each are incorporated herein by reference.

### BACKGROUND

### Technical Field

The present disclosure relates to a semiconductor device.

### Background Art

Radio-frequency power amplifiers including heterojunction bipolar transistors (HBTs) can be used in communication devices in mobile communication systems. To enhance the efficiency of HBT, achieving higher heat dissipation characteristics is desired. When temperature uniformity is not consistently achieved in an HBT, a larger amount of current flows into a particular region of the HBT, resulting in current collapse. This current collapse degrades the output characteristic. Japanese Unexamined Patent Application Publication No. 2005-243897 listed below discloses an HBT having an emitter electrode elongated in one direction; in the HBT, a high degree of temperature uniformity in the longitudinal direction of the emitter electrode is achieved.

In the HBT disclosed in Japanese Unexamined Patent Application Publication No. 2005-243897, an emitter electrode wire is disposed directly over the emitter electrode with an interlayer insulating film interposed between the emitter electrode wire and the emitter electrode. The emitter electrode wire is coupled to the emitter electrode through a contact hole formed in the interlayer insulating film. An emitter wire is coupled to a portion of the emitter electrode wire, not including the end portions of the emitter electrode wire in the longitudinal direction of the emitter electrode wire. The emitter wire is thermally coupleable to a substrate through a via-hole formed in the interlayer insulating film. Because the emitter wire serves as a heat transfer path from the HBT to the substrate, the efficiency of heat dissipation from the middle portion of the emitter electrode wire, at which temperature tends to become relatively high, is increased. With the increased efficiency of heat dissipation, the temperature uniformity in the longitudinal direction of the emitter electrode wire is enhanced. As a result, the temperature uniformity in the longitudinal direction of the emitter electrode coupled to the emitter electrode wire is in turn enhanced in an indirect manner.

### SUMMARY

Accordingly, the present disclosure provides a semiconductor device in which the temperature uniformity in a bipolar transistor in operation is enhanced.

According to an aspect of the present disclosure, there is provided a semiconductor device including a bipolar transistor disposed above the substrate. The bipolar transistor includes a collector layer, a base layer, and an emitter layer that are stacked in order from a substrate side. The semiconductor device also includes at least one emitter electrode disposed above the emitter layer, and the emitter electrode is electrically coupled to the emitter layer. The semiconductor device further includes an interlayer insulating film disposed on the emitter electrode, with an emitter contact hole formed in the interlayer insulating film, and the emitter contact hole being surrounded by the emitter electrode when viewed in plan view. The semiconductor device also includes an emitter wire disposed on the interlayer insulating film, and the emitter wire is coupled to the emitter electrode through the emitter contact hole. When viewed in plan view, the emitter electrode and the emitter contact hole are elongated in one direction. A first condition is satisfied with respect to the at least one emitter electrode and the emitter contact hole surrounded by the emitter electrode when viewed in plan view. In the first condition, the length of the emitter contact hole is 85% or less of the length of the emitter electrode, and of two side ends of the emitter electrode, the distance from each side end to the emitter contact hole is 5% or more of the length of the emitter electrode.

The emitter electrode and the emitter contact hole satisfy the first condition. This configuration thus enhances the temperature uniformity in the longitudinal direction of the emitter electrode.

### BRIEF DESCRIPTION OF THE DRAWINGS

FIG. 1 is a schematic plan view of a semiconductor device according to a first embodiment;

FIG. 2 is a sectional view taken along dot-dash line 2-2 in FIG. 1;

FIG. 3 provides a graph illustrating an exemplary temperature distribution in a bipolar transistor and an exemplary temperature distribution in another bipolar transistor along the x axis with respect to positional relationships between an emitter electrode and an emitter contact hole;

FIG. 4 is a graph illustrating a result of measuring breakdown input power against the ratio of the length of the emitter contact hole to the length of the emitter electrode;

FIG. 5 is a schematic plan view of a semiconductor device according to a second embodiment;

FIG. 6 is a schematic plan view of a semiconductor device according to a modification of the second embodiment;

FIG. 7 is a schematic plan view of a semiconductor device according to a third embodiment; and

FIG. 8 is a sectional view taken along dot-dash line 8-8 in FIG. 7.

### DETAILED DESCRIPTION

### First Embodiment

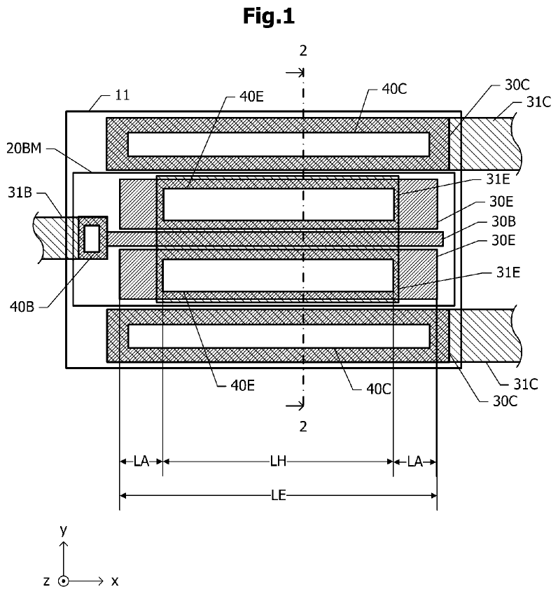

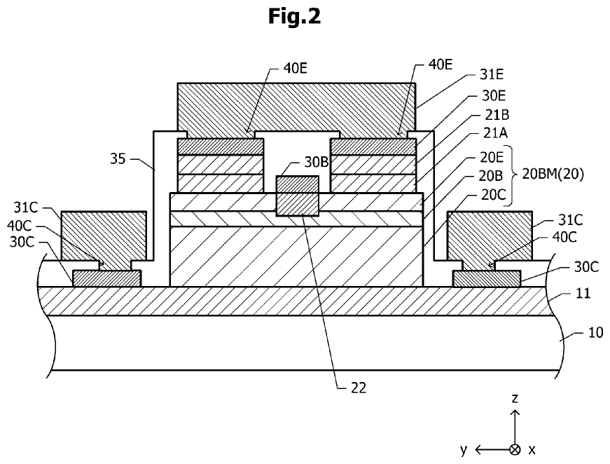

A semiconductor device according to a first embodiment will be described with reference to the drawings of FIGS. 1 to 4. FIG. 1 is a schematic plan view of a semiconductor device according to the first embodiment. An n-type conductive subcollector layer 11 is disposed on a top layer of a substrate 10 (the substrate 10 will be described later with reference to FIG. 2). An xyz orthogonal coordinate system is provided in which xy indicates a plane parallel to the surface of the substrate 10, and the z axis is along the normal line to the surface of the substrate 10.

When viewed in plan view, a base mesa 20BM and a pair of collector electrodes 30C are surrounded by the subcollector layer 11. The base mesa 20BM includes a collector layer 20C, a base layer 20B, and an emitter layer 20E as will be described later with reference to FIG. 2. The base mesa 20BM is positioned between the pair of collector electrodes 30C along the y axis.

When viewed in plan view, a pair of emitter electrodes 30E and a base electrode 30B are surrounded by the base mesa 20BM. The base electrode 30B is positioned between the pair of emitter electrodes 30E along the y axis. In FIG. 1, the collector electrodes 30C, the emitter electrodes 30E, and the base electrode 30B are hatched with diagonal lines from upper right to lower left. The regions of emitter contact holes 40E, the regions of collector contact holes 40C, and the region of a base contact hole 40B, which will be described later, are left white.

Each emitter electrode 30E is elongated in one direction (the x axis) when viewed in plan view. For example, the shape of the emitter electrodes 30E is a rectangle elongated along the x axis when viewed in plan view. The base electrode 30B extends along the x axis from one end to the other end of the area occupied by the emitter electrodes 30E; the base electrode 30B extends beyond one ends of the emitter electrodes 30E along the x axis (to the left in FIG. 1). The length of the base electrode 30B may be less than or about equal to the length of the emitter electrodes 30E.

The collector electrodes 30C, the emitter electrodes 30E, and the base electrode 30B are covered by an interlayer insulating film 35 (FIG. 2). The emitter contact holes 40E, the collector contact holes 40C, and the base contact hole 40B are formed in the interlayer insulating film 35. The emitter contact holes 40E are formed for the respective emitter electrodes 30E. When viewed in plan view, the emitter contact holes 40E are surrounded by the corresponding emitter electrodes 30E. The collector contact holes 40C are formed for the respective collector electrodes 30C. When viewed in plan view, the collector contact holes 40C are surrounded by the corresponding collector electrodes 30C. The base contact hole 40B is surrounded by a portion of the base electrode 30B, extending beyond the one ends of the emitter electrodes 30E along the x axis.

Two collector wires 31C, an emitter wire 31E, and a base wire 31B are disposed on the interlayer insulating film 35 (FIG. 2). In FIG. 1, the collector wires 31C, the emitter wire 31E, and the base wire 31B are hatched with diagonal lines from upper left to lower right in shades lighter than the hatching of the electrodes including the emitter electrodes

The two collector wires 31C respectively overlap the two collector electrodes 30C when viewed in plan view. The collector wires 31C are coupled to the collector electrodes through the collector contact holes 40C. The collector wires 31C further extend, from the portions coinciding with the collector electrodes 30C of the collector wires 31C, in one direction along the x axis (to the right in FIG. 1) to the outside beyond the subcollector layer 11.

The emitter wire 31E overlaps a portion of each of the two emitter electrodes 30E when viewed in plan view, and the emitter wire 31E is disposed across the base electrode 30B. The two emitter contact holes 40E are surrounded by the emitter wire 31E when viewed in plan view. The emitter wire 31E is coupled to the two emitter electrodes 30E through the emitter contact holes 40E.

The base wire 31B overlaps the portion extending beyond the one ends of the emitter electrodes 30E along the x axis of the base electrode 30B and further extends away from the emitter electrodes 30E (to the left in FIG. 1). The base wire 31B is coupled to the base electrode 30B through the base contact hole 40B.

LH indicates the length (the measurement along the x axis) of each emitter contact hole 40E. LE indicates the length (the measurement along the x axis) of each emitter electrode 30E. LA indicates the distance from each of the two side ends of the emitter electrode 30E to the emitter contact hole 40E along the x axis. The length LH is 85% or less of the length LE. The distance LA is 5% or more of the length LE.

FIG. 2 is a sectional view taken along dot-dash line 2-2 in FIG. 1. The subcollector layer 11 is disposed on the substrate 10. The base mesa 20BM is disposed on a region of the subcollector layer 11. The base mesa 20BM includes the collector layer 20C, the base layer 20B, and the emitter layer 20E, which are stacked in order from the substrate 10 side. The collector layer 20C, the base layer 20B, and the emitter layer 20E form a bipolar transistor 20. A pair of cap layers 21A are disposed on the base mesa 20BM across a gap along the y axis. The contact layers 21B are disposed on the cap layers 21A.

In one example, semi-insulating GaAs is used for the substrate 10. The subcollector layer 11 and the collector layer 20C are made of n-type GaAs. The base layer 20B is made of p-type GaAs. The emitter layer 20E is made of n-type InGaP. The cap layers 21A are made of n-type GaAs. The contact layers 21B are made of n-type InGaAs. This means that the bipolar transistor 20 is a heterojunction bipolar transistor.

The emitter electrodes 30E are respectively disposed on the pair of contact layers 21B. The emitter electrodes 30E are electrically coupled to the emitter layer 20E through the contact layers 21B and the cap layers 21A. When viewed in plan view, the emitter electrodes 30E almost coincide with the contact layers 21B and the cap layers 21A. For example, the contact layers 21B and the cap layers 21A are formed in a self-aligned manner with the use of the emitter electrodes 30E as an etch mask by etch removing unnecessary portions.

The base electrode 30B is disposed between the pair of cap layers 21A on the emitter layer 20E. The base electrode 30B is electrically coupled to the base layer 20B through an alloyed region 22. The alloyed region 22 extends through the emitter layer 20E in the thickness direction of the emitter layer 20E.

The collector electrodes 30C are disposed on both sides of the subcollector layer 11 with respect to the base mesa 20BM. The collector electrodes 30C are electrically coupled to the collector layer 20C through the subcollector layer 11.

The interlayer insulating film 35 is disposed over the entire region of the substrate covering the emitter electrodes 30E, the base electrode 30B, and the collector electrodes 30C. The emitter contact holes 40E and the collector contact holes 40C are formed in the interlayer insulating film 35. As described with reference to FIG. 1, the emitter contact holes 40E are surrounded by the emitter electrodes 30E when viewed in plan view, and the collector contact holes 40C are surrounded by the collector electrodes 30C when viewed in plan view.

The first-layer emitter wire 31E and the collector wires 31C are disposed on the interlayer insulating film 35. The emitter wire 31E extends from one of the emitter electrodes 30E through the part above the base electrode 30B to the other of the emitter electrodes 30E. The emitter wire 31E connects the two emitter electrodes 30E to each other through the emitter contact holes 40E.

The collector wires 31C are coupled to the collector electrodes 30C through the collector contact holes 40C.

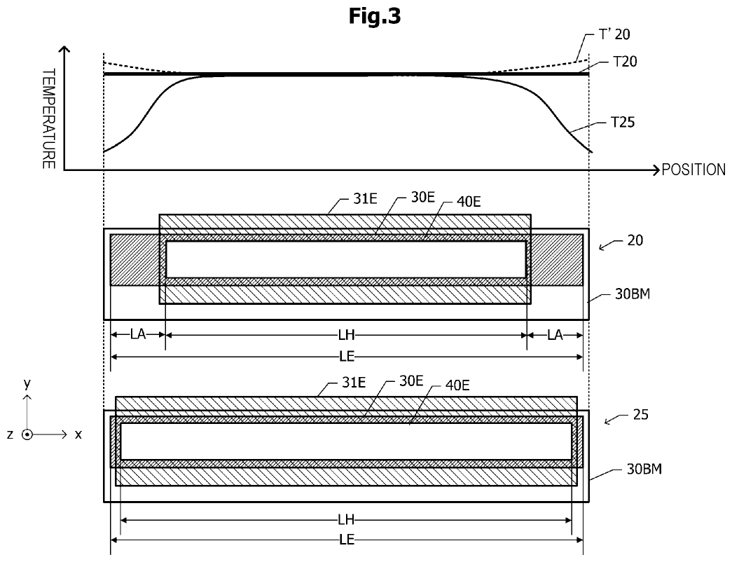

The following describes advantageous effects of the first embodiment with reference to FIG. 3. FIG. 3 provides a graph illustrating an exemplary temperature distribution in the bipolar transistor 20 and an exemplary temperature distribution in a bipolar transistor 25 along the x axis with respect to positional relationships between the emitter electrode 30E and the emitter contact hole 40E. The positional relationship between the emitter electrode and the emitter contact hole 40E of the bipolar transistor 20 is the same as the positional relationship in the semiconductor device according to the first embodiment. Specifically, the length LH of the emitter contact hole 40E is 85% or less of the length of the emitter electrode 30E. The distance LA, which is the distance from each end of the emitter electrode 30E to the emitter contact hole 40E along the x axis, is 5% or more of the length LE of the emitter electrode 30E.

In the bipolar transistor 25, which is a comparative example, the emitter electrode and the emitter contact hole 40E do not satisfy the condition described above (referred to as the “first condition” in this specification). Specifically, the length LH of the emitter contact hole 40E is longer than 85% of the length LE of the emitter electrode 30E.

An exemplary temperature distribution in the bipolar transistor 20 along the x axis and an exemplary temperature distribution in the bipolar transistor 25 along the x axis are respectively represented by solid lines T20 and T25. Heat generated in the bipolar transistor 20 (FIG. 2) is transferred to the emitter wire 31E through the emitter electrodes 30E. The heat transferred the emitter wire 31E is further transferred to, for example, an external component coupled to the emitter wire 31E, such as a module substrate. The heat transfer path from the emitter electrode 30E to the emitter wire 31E is physically limited within the emitter contact hole 40E.

In the bipolar transistor 25 according to the comparative example, the thermal resistance in the heat transfer path from the emitter electrode 30E to the emitter wire 31E is almost consistent throughout almost the entire region in the length direction of the emitter electrode 30E. Among in-plane directions on the substrate 10, at the ends of the emitter electrode 30E, heat diffuses in three directions: both directions along the y axis and one direction along the x axis. At the middle portion in the length direction of the emitter electrode 30E, heat diffuses in only both directions along the y axis. As a result, the temperature distribution along the x axis indicates that temperature is lower near the end portions of the emitter electrode 30E than the middle portion, as indicated by the solid line T25.

By contrast, in the bipolar transistor 20 according to the first embodiment, the emitter contact hole 40E does not extend to the regions near the both end portions of the emitter electrode 30E. As a result, the thermal resistance in the heat transfer path from the emitter electrode 30E to the emitter wire 31E is relatively high near the both end portions of the emitter electrode 30E. This configuration inhibits decreases in temperature near the both end portions of the emitter electrode 30E as indicated by the solid line T20, thereby enhancing the uniformity of temperature distribution in the bipolar transistor 20 along the x axis.

Depending on the positional relationship between the emitter electrode 30E and the emitter contact hole 40E, the temperature distribution can indicate that temperature gradually increases from the middle of the emitter electrode 30E to the ends of the emitter electrode 30E, as indicated by a dashed line T′20 in the graph in FIG. 3. Also in this case, fluctuations in the temperature distribution represented by the dashed line T′20 are smaller than fluctuations in the temperature distribution represented by the solid line T25.

As illustrated in FIG. 3, in the first embodiment, the uniformity of temperature distribution in the bipolar transistor 20 (FIG. 1) along the x axis is enhanced. This enhanced uniformity of temperature distribution reduces the effect of current collapse, which is likely to occur when the collector voltage is increased, and enables stable operation with high voltage.

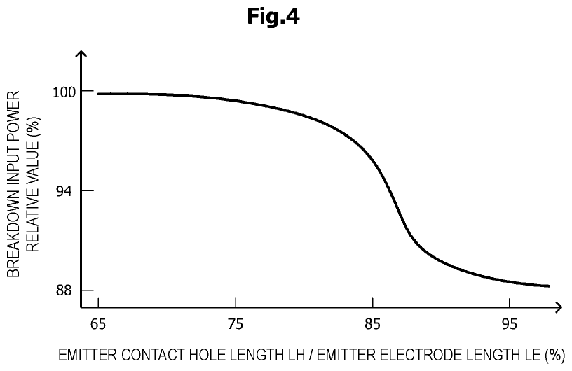

The following describes a preferred positional relationship between the emitter electrode 30E and the emitter contact hole 40E with reference to FIG. 4.

FIG. 4 is a graph illustrating an actual result of measuring breakdown input power on multiple samples made with different ratios of the length LH of the emitter contact hole 40E to the length LE of the emitter electrode 30E. The horizontal axis indicates LH/LE in units of “%”, and the vertical axis indicates relative value of breakdown input power in units of “%”. A load variation test was conducted under a condition in which the frequency is 2.5 GHz, the collector voltage is 5.5V, and the voltage standing wave ratio (VSWR) is 4.2, while input power is gradually increased. The input power with which the device breaks in the load variation test corresponds to breakdown input power.

It can be seen that when the ratio of the length LH to the length LE increases beyond 85%, breakdown input power significantly decreases. To inhibit decreases in breakdown input power, it is preferable that the ratio of the length LH to the length LE be 85% or less as in the semiconductor device according to the first embodiment (FIG. 1).

If the emitter contact hole 40E is shifted to either side of the emitter electrode 30E with respect to the x axis, the symmetry of temperature distribution is destroyed, and the uniformity of temperature distribution deteriorates. To achieve the uniformity of temperature distribution, it is preferable that the distance LA (FIG. 1), which is the distance from each end of the emitter electrode 30E to the emitter contact hole 40E, be 5% or more of the length LE of the emitter electrode 30E. It is more preferable that the center of the emitter contact hole 40E coincide with the center of the emitter electrode 30E with respect to the x axis.

The following describes a modification of the first embodiment. In the first embodiment, although the positional relationship between the emitter electrode 30E and the emitter contact hole 40E is specified, the position and size of the emitter wire 31E is not particularly specified. The emitter wire 31E may be positioned such that when viewed in plan view, the emitter contact hole 40E is surrounded by the emitter wire 31E, and the emitter wire 31E extends to the ends of the emitter electrode 30E along the x axis. In this case, when viewed in plan view, the emitter wire 31E overlaps the emitter electrode 30E near the ends of the emitter electrode 30E, at which the emitter contact hole 40E is not formed, but the interlayer insulating film 35 is interposed between the emitter wire 31E and the emitter electrode 30E (FIG. 2).

The thermal conductivity of the interlayer insulating film 35 is lower than the thermal conductivity of the emitter wire 31E. Accordingly, the thermal resistance in the heat transfer path from the emitter electrode 30E to the emitter wire 31E in the region without the emitter contact hole 40E is higher than the thermal resistance in the heat transfer path in the region having the emitter contact hole 40E. This configuration inhibits decreases in temperature near the ends of the emitter electrode 30E, although the emitter wire 31E extends to the ends of the emitter electrode 30E along the x axis. This configuration thus accomplishes the advantageous effect of achieving the uniformity of temperature distribution.

When viewed in plan view, it is preferable that the emitter wire 31E be disposed within the region having the base mesa 20BM with respect to the x axis, as illustrated in FIG. 1. There is a difference in level at edges of the base mesa 20BM as illustrated in FIG. 2. The disposition of the emitter wire 31E within the area having the base mesa 20BM with respect to the x axis inhibits wire breakdown due to this difference in level. Similarly, it is also preferable that the emitter wire 31E be disposed within the area having the base mesa 20BM with respect to the y axis.

The semiconductor device according to the first embodiment includes the two emitter electrodes 30E, but the semiconductor device according to the first embodiment may include one emitter electrode 30E. Also in this case, when the positional relationship between the emitter electrode 30E and the emitter contact hole 40E satisfies the first condition of the first embodiment, the uniformity of temperature distribution in the bipolar transistor 20 along the x axis is enhanced.

### Second Embodiment

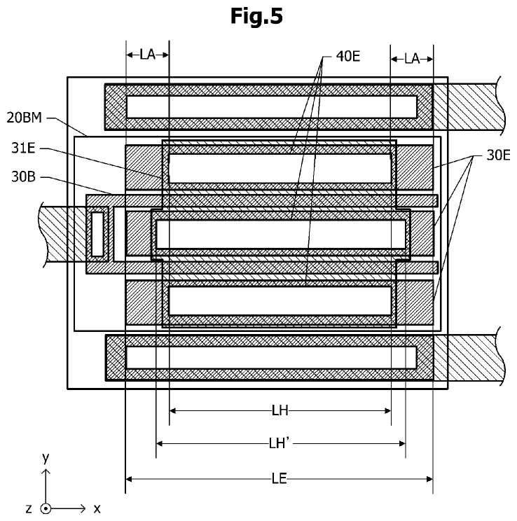

The following describes a semiconductor device according to a second embodiment with reference to FIG. 5. In the following, descriptions of the configurational features in common with the semiconductor device according to the first embodiment described with reference to the drawings of FIGS. 1 to 4 will not be repeated.

FIG. 5 is a schematic plan view of a semiconductor device according to the second embodiment. In the first embodiment (FIG. 1), when viewed in plan view, two emitter electrodes 30E are surrounded by the base mesa 20BM. By contrast, in the second embodiment, three emitter electrodes 30E are surrounded by the base mesa 20BM. The cap layer 21A and the contact layer 21B (FIG. 2) are disposed below each emitter electrode 30E.

Each of the three emitter electrodes 30E is elongated along the x axis when viewed in plan view. The three emitter electrodes 30E are arranged along the y axis. The three emitter electrodes 30E have the same length, LE. Base electrodes 30B are disposed between the emitter electrode 30E in the middle and the respective emitter electrodes 30E on both sides. The base electrodes 30B are connected with each other at the region not overlapping the emitter electrodes 30E.

Three emitter contact holes 40E are formed such that the three emitter contact holes are respectively surrounded by the three emitter electrodes 30E. The emitter wire 31E couples the three emitter electrodes 30E to each other.

The emitter electrodes 30E and the emitter contact holes 40E on two sides in the width direction (they axis) of the emitter electrodes 30E satisfy the first condition described above. Specifically, the length LH is 85% or less of the length LE, and the distance LA is 5% or more of the length LE. A length LH′ of the emitter contact hole 40E in the middle with respect to the y axis is longer than the length LH of the emitter contact holes 40E on two sides. With respect to the x axis, the area having the emitter contact holes 40E on two sides is surrounded by the area having the emitter contact hole 40E in the middle. The emitter electrode 30E in the middle and the emitter contact hole 40E do not need to satisfy the first condition.

The measurement along the x axis of the emitter wire 31E varies in a terraced manner along the y axis, depending on the length LH of the emitter contact hole 40E. Specifically, the measurement along the x axis of a portion overlapping the emitter contact hole 40E in the middle of the emitter wire 31E is larger than the measurement along the x axis of portions overlapping the emitter contact holes 40E on two sides.

The following describes an advantageous effect of the second embodiment. In the second embodiment, the uniformity of temperature distribution along the x axis in the emitter electrodes 30E positioned on two sides with respect to the y axis is enhanced. Because the emitter electrode 30E in the middle is positioned between the other emitter electrodes 30E on both sides with respect to the y axis, the amount of heat diffusing in in-plane directions from the ends of the emitter electrode 30E is smaller than the amount of heat diffusing in in-plane directions from the ends of the emitter electrodes 30E positioned on two sides with respect to the y axis. As a result, at the middle portion with respect to the x axis of the emitter electrode 30E in the middle, temperature decreases less than at two end portions with respect to the x axis of the emitter electrode 30E in the middle. This configuration achieves a sufficient degree of temperature uniformity along the x axis when the emitter electrode 30E in the middle and the emitter contact hole 40E do not satisfy the first condition.

Temperature increases in the emitter electrode 30E in the middle more than in the emitter electrodes 30E on two sides. In the second embodiment, the emitter contact hole 40E in the middle is longer than the emitter contact holes 40E on two sides. As a result, the amount of heat transferred from the emitter electrode 30E in the middle to the emitter wire 31E is larger than from the emitter electrodes 30E on two sides. A relatively large amount of heat is dissipated from the emitter electrode 30E in the middle, which tends to be heated to a relatively high temperature. This configuration enhances the temperature uniformity among the three emitter electrodes 30E. This enhanced uniformity of temperature distribution reduces the effect of unbalanced currents in the emitter electrodes which is likely to occur when the collector voltage is increased, and enables stable operation with high voltage.

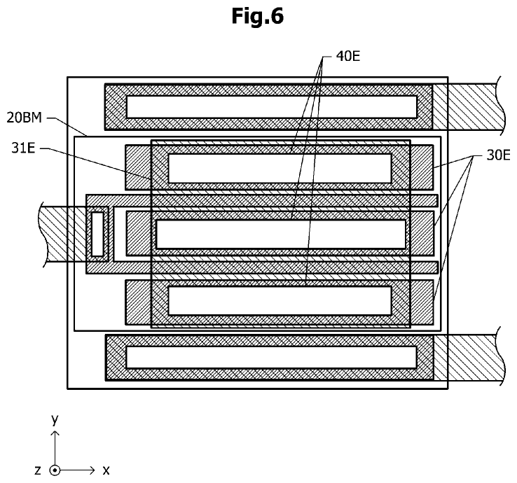

The following describes a modification of the second embodiment with reference to FIG. 6. FIG. 6 is a schematic plan view of a semiconductor device according to a modification of the second embodiment. In the second embodiment (FIG. 5), the measurement along the x axis of the emitter wire 31E varies in a terraced manner along the y axis, depending on the length LH of the emitter contact hole 40E. By contrast, in the modification illustrated in FIG. 6, the measurement along the x axis is the same throughout the emitter wire 31E. Also in this modification, the length LH varies among the three emitter contact holes 40E. This configuration, similarly to the second embodiment, enhances the temperature uniformity along the x axis and also enhances the temperature uniformity in the three emitter electrodes 30E.

The following describes another modification of the second embodiment. In the second embodiment, when viewed in plan view, three emitter electrodes 30E are surrounded by one base mesa 20BM, but four or more emitter electrodes 30E may be surrounded by one base mesa 20BM.

### Third Embodiment

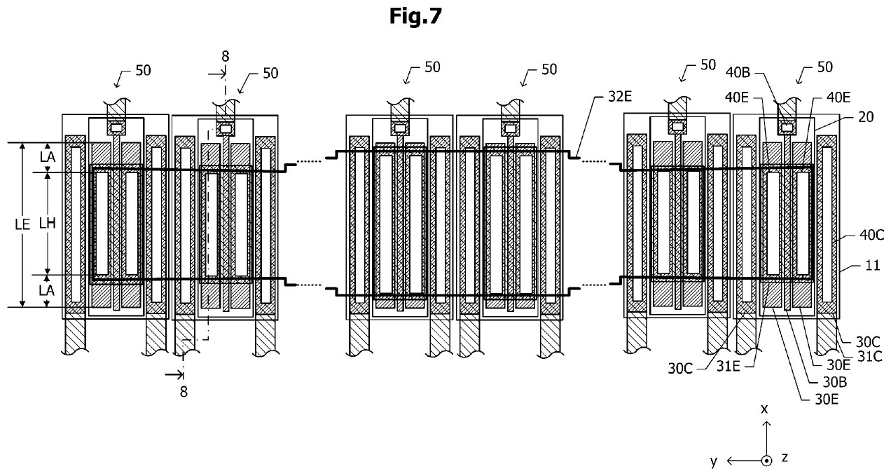

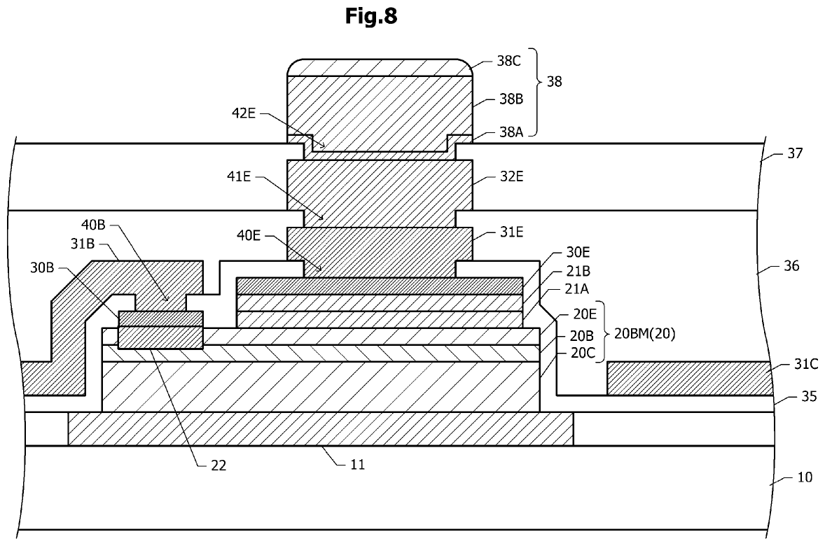

The following describes a semiconductor device according to a third embodiment with reference to FIGS. 7 and 8. In the following, descriptions of the configurational features in common with the semiconductor device according to the first embodiment described with reference to the drawings of FIGS. 1 to 4 will not be repeated.

FIG. 7 is a schematic plan view of a semiconductor device according to the third embodiment. In the first embodiment, one bipolar transistor 20 and other elements including the emitter electrodes 30E coupled to the bipolar transistor 20 have been described. By contrast, the semiconductor device according to the third embodiment includes three or more bipolar transistors 20.

Three or more cells 50 are arranged along the y axis on the substrate 10 (FIG. 8), which will be described later. The cells 50 are coupled in parallel to each other. The basic configuration of each cell 50 is the same as the configuration of the semiconductor device according to the first embodiment. Specifically, each cell 50 includes the bipolar transistor 20, the two emitter electrodes 30E, the two collector electrodes 30C, the base electrode 30B, and the emitter wire 31E. The cells 50 are covered by the interlayer insulating film 35 (FIG. 8), which will be described later. The emitter contact holes 40E are formed in the interlayer insulating film 35 (FIG. 8), corresponding to the respective emitter electrodes 30E. The emitter electrodes 30E and the emitter contact holes 40E are elongated along the x axis when viewed in plan view. The length LE of the emitter electrode 30E is the same in all the cells 50.

The collector contact holes 40C and the base contact hole 40B are formed in the interlayer insulating film 35 (FIG. 8). The collector wires 31C are coupled to the collector electrodes 30C through the collector contact holes 40C. The base wire 31B are coupled to the base electrode 30B through the base contact hole 40B.

When viewed in plan view, a second-layer emitter wire 32E is disposed on the emitter wires 31E of the cells 50 arranged along the y axis. The second-layer emitter wire 32E couples the first-layer emitter wires 31E to each other.

The cells 50 on two sides with respect to the y axis satisfy the first condition, which is satisfied by the semiconductor device according to the first embodiment. Specifically, the length LH of the emitter contact hole 40E is 85% or less of the length LE of the emitter electrode 30E. The distance LA, which is the distance from each of the two side ends of the emitter electrode 30E to the emitter contact hole 40E along the x axis, is 5% or more of the length LE of the emitter electrode 30E.

In each cell 50, the length LH is the same between the two emitter contact holes 40E of the cell 50. Between two cells 50 adjacent to each other along they axis, one cell 50 closer to an end with respect to the y axis has the length LH of the emitter contact hole 40E shorter than or equal to the length LH of the emitter contact hole 40E of the other cell 50. This means that the length LE of the emitter contact hole 40E increases from the cells 50 on both sides with respect to the y axis to the cells 50 on the inside. The cells 50 other than the cells 50 on both sides with respect to the y axis do not necessarily satisfy the first condition.

The measurement along the x axis of the emitter wire 31E varies among the cells 50, depending on the length LH of the emitter contact hole 40E. This means that the length LE of the emitter electrode 30E increases from the cells 50 on both sides with respect to the y axis to the cells 50 on the inside. The measurement along the x axis of the second-layer emitter wire 32E increases from both sides with respect to the y axis to the inside, corresponding to the measurement along the x axis of the first-layer emitter wire 31E.

FIG. 8 is a sectional view taken along dot-dash line 8-8 in FIG. 7. The subcollector layer 11 is disposed on a top layer of the substrate 10. The base mesa 20BM is disposed on the subcollector layer 11. The base mesa 20BM includes the collector layer 20C, the base layer 20B, and the emitter layer 20E. The collector layer 20C, the base layer 20B, and the emitter layer 20E form the bipolar transistor 20. The cap layer 21A is disposed on the emitter layer 20E, and the contact layer 21B is disposed on the cap layer 21A. The emitter electrode 30E is disposed on the contact layer 21B.

The base electrode 30B is disposed on the emitter layer 20E across a gap from the cap layer 21A in an in-plane direction. The base electrode 30B is electrically coupled to the base layer 20B through the alloyed region 22.

The interlayer insulating film 35 is disposed over the entire region of the substrate 10, covering elements including the emitter electrode 30E and the base electrode 30B. The emitter contact hole 40E and the base contact hole 40B are formed in the interlayer insulating film 35. The emitter wire 31E, the base wire 31B, and the collector wires 31C are disposed on the interlayer insulating film 35. The emitter wire 31E is coupled to the emitter electrode 30E through the emitter contact hole 40E. The base wire 31B is coupled to the base electrode 30B through the base contact hole 40B. The collector wire 31C is coupled to the collector electrode 30C (FIG. 7) through the collector contact hole 40C (FIG. 7).

A second-layer interlayer insulating film 36 is disposed covering the emitter wire 31E, the base wire 31B, and the collector wire 31C. An emitter contact hole 41E is formed in the interlayer insulating film 36. The emitter contact hole 41E is surrounded by the emitter wire 31E when viewed in plan view. The second-layer emitter wire 32E, which is disposed on the interlayer insulating film 36, is coupled to the first-layer emitter wire 31E through the emitter contact hole 41E.

An insulating protective film 37 is disposed on the interlayer insulating film 36, covering the second-layer emitter wire 32E. A cavity 42E is formed in the protective film 37. The cavity 42E is surrounded by the second-layer emitter wire 32E when viewed in plan view. A conductive raised portion 38 is disposed on the protective film 37. The cavity 42E is surrounded by the conductive raised portion 38 when viewed in plan view. The conductive raised portion 38 is usable as a terminal to be coupled to an external circuit such as a module substrate.

The conductive raised portion 38 includes an under-bump metal layer 38A, a Cu pillar 38B, and a solder layer 38C that are stacked in order from the substrate 10 side. The conductive raised portion 38 having such a structure is referred to as a Cu pillar bump. Instead of a Cu pillar bump, for example, an Au bump, a solder ball bump, or a conductive post held on a pad may be used as the conductive raised portion 38. The semiconductor device according to the third embodiment can be flip-chip mounted such that the surface having the conductive raised portion 38 faces a module substrate.

The following describes an advantageous effect of the third embodiment. Heat generated in the bipolar transistor 20 in the semiconductor device according to the third embodiment is transferred through the emitter electrodes 30E, the first-layer emitter wire 31E, the second-layer emitter wire 32E, and the conductive raised portion 38 to, for example, a module substrate. The first-layer emitter wire 31E is in direct contact with the emitter electrode 30E through the emitter contact hole 40E, whereas the second-layer emitter wire 32E and the conductive raised portion 38 are not in direct contact with the emitter electrode 30E. As a result, the temperature distribution in the longitudinal direction of the emitter electrode 30E is greatly affected by the positional relationship between the emitter contact hole 40E and the emitter electrodes 30E. The temperature distribution in the longitudinal direction of the emitter electrode 30E is not greatly affected by the relative positional relationship between the emitter electrode 30E and the second-layer emitter wire 32E. Similarly, the temperature distribution in the longitudinal direction of the emitter electrode is also not greatly affected by the relative positional relationship between the emitter electrode 30E and the conductive raised portion 38.

In the third embodiment, the cells 50 on two sides with respect to the y axis satisfy the first condition similarly to the semiconductor device according to the first embodiment. This configuration enhances the uniformity of temperature distribution in the bipolar transistor 20 in the length direction of the emitter electrode 30E.

In the arrangement in which the cells 50 are aligned along the y axis as in the third embodiment, the temperature of the cells 50 in the middle portion with respect to the y axis tends to be higher than the temperature of the cells 50 on two sides. In the third embodiment, the emitter contact holes 40E of the cells 50 in the middle portion are longer than the emitter contact holes 40E of the cells 50 on two sides. As a result, the heat dissipation characteristic of the cells 50 in the middle portion is higher than the heat dissipation characteristic of the cells 50 on two sides. The heat dissipation characteristic of the cells 50 that tend to be heated to a relatively high temperature is relatively high. This configuration thus enhances the temperature uniformity in the cells 50. This enhanced temperature uniformity in the cells 50 leads to an advantageous effect in which the breakdown tolerance of an amplifier circuit including the cells 50 coupled in parallel with each other is improved.

Usually, metallic materials are used for members in the heat transfer path from the emitter electrode 30E to the conductive raised portion 38. The thermal conductivity of metallic materials is higher than the thermal conductivity of the substrate 10 made of a material such as a semiconductor. Hence, as compared to the configuration in which heat generated in the bipolar transistor 20 is released toward the substrate 10 side, the heat dissipation characteristic of the semiconductor device according to the third embodiment is improved.

The following describes a modification of the third embodiment. In the third embodiment, each cell 50 includes two emitter electrodes 30E with two emitter contact holes 40E; similarly to the semiconductor device according to the second embodiment (FIG. 5), each cell 50 may include three emitter electrodes 30E; alternatively, each cell 50 may include four or more emitter electrodes 30E. When three or more emitter electrodes 30E are included, the emitter contact holes 40E formed for the respective emitter electrodes 30E do not necessarily have the same length.

When the emitter contact holes 40E of different lengths are formed in the cells 50, it is sufficient that between two cells 50 adjacent to each other along the y axis, the shortest emitter contact hole 40E among the emitter contact holes 40E of one cell 50 closer to an end with respect to the y axis be shorter than or equal to the shortest emitter contact hole 40E among the emitter contact holes 40E of the other cell 50.

In the third embodiment, the measurement along the x axis of the second-layer emitter wire 32E varies along the y axis, depending on the measurement along the x axis of the first-layer emitter wire 31E. However, the measurement along the x axis of the second-layer emitter wire 32E may be consistent. The temperature distribution in the longitudinal direction of the emitter electrode 30E is not greatly affected by the positional relationship between the emitter electrode 30E and the second-layer emitter wire 32E. Hence, when the measurement along the x axis of the second-layer emitter wire 32E is consistent, similarly to the third embodiment, this configuration achieves an advantageous effect in which the uniformity of temperature distribution is enhanced.

The embodiments described above are merely examples, and as might be expected, the configurational features described in the different embodiments may be partially replaced or combined. The same effects and advantages achieved by the same configuration features among the multiple embodiments are not mentioned in every embodiment. Furthermore, the present disclosure is not limited to the embodiments described above. For example, various modifications, improvements, and combinations would be apparent to those skilled in the art.

What is claimed is:

1. A semiconductor device comprising:
a substrate;
a bipolar transistor above the substrate, the bipolar transistor including a collector layer, a base layer, and an emitter layer that are stacked in order from a substrate side;
at least one emitter electrode above the emitter layer, the emitter electrode being electrically coupled to the emitter layer;
an interlayer insulating film on the emitter electrode, and at least one emitter contact hole in the interlayer insulating film, the emitter contact hole being surrounded by the emitter electrode when viewed in plan view; and
an emitter wire on the interlayer insulating film, the emitter wire being coupled to the emitter electrode through the emitter contact hole, wherein
when viewed in plan view, the emitter electrode and the emitter contact hole are elongated in one direction, and
a first condition is satisfied with respect to the at least one emitter electrode and the emitter contact hole surrounded by the emitter electrode when viewed in plan view; such that in the first condition, a length of the emitter contact hole is 85% or less of a length of the emitter electrode, and of two side ends of the emitter electrode, a distance from each side end to the emitter contact hole is 5% or more of the length of the emitter electrode.

2. The semiconductor device according to claim 1, wherein
the emitter wire is within an area having the collector layer and the base layer in a longitudinal direction of the emitter electrode.

3. The semiconductor device according to claim 1, wherein
the at least one emitter electrode includes three or more emitter electrodes arranged in a width direction perpendicular to a longitudinal direction of the emitter electrode when viewed in plan view, and the emitter electrodes are identical in length to each other,
the at least one emitter contact hole includes emitter contact holes for the respective emitter electrodes,
the first condition is satisfied with respect to emitter electrodes on two sides in the width direction among the three or more emitter electrodes and corresponding emitter contact holes among the emitter contact holes, and
an emitter contact hole other than the corresponding emitter contact holes on two sides in the width direction among the emitter contact holes is longer than the corresponding emitter contact holes on two sides.

4. The semiconductor device according to claim 1, further comprising:
a conductive raised portion on the emitter wire, the conductive raised portion being configured to be coupled to an external circuit, wherein
the conductive raised portion is electrically coupled to the emitter wire.

5. The semiconductor device according to claim 2, wherein
the at least one emitter electrode includes three or more emitter electrodes arranged in a width direction perpendicular to a longitudinal direction of the emitter electrode when viewed in plan view, and the emitter electrodes are identical in length to each other,
the at least one emitter contact hole includes emitter contact holes for the respective emitter electrodes,
the first condition is satisfied with respect to emitter electrodes on two sides in the width direction among the three or more emitter electrodes and corresponding emitter contact holes among the emitter contact holes, and
an emitter contact hole other than the corresponding emitter contact holes on two sides in the width direction among the emitter contact holes is longer than the corresponding emitter contact holes on two sides.

6. The semiconductor device according to claim 2, further comprising:
a conductive raised portion on the emitter wire, the conductive raised portion being configured to be coupled to an external circuit, wherein
the conductive raised portion is electrically coupled to the emitter wire.

7. The semiconductor device according to claim 3, further comprising:
a conductive raised portion on the emitter wire, the conductive raised portion being configured to be coupled to an external circuit, wherein
the conductive raised portion is electrically coupled to the emitter wire.

8. The semiconductor device according to claim 5, further comprising:
a conductive raised portion on the emitter wire, the conductive raised portion being configured to be coupled to an external circuit, wherein
the conductive raised portion is electrically coupled to the emitter wire.

9. A semiconductor device comprising:
a substrate;
three or more cells arranged in a first direction on the substrate;
an interlayer insulating film covering the cells; and
an emitter wire on the interlayer insulating film, wherein
each cell includes
a bipolar transistor including a collector layer, a base layer, and an emitter layer that are stacked in order from a substrate side, and
at least one emitter electrode above the emitter layer, the emitter electrode being electrically coupled to the emitter layer,
an emitter contact hole is in the interlayer insulating film for the emitter electrode of each cell, and the emitter contact hole is surrounded by the emitter electrode when viewed in plan view,
the emitter wire is coupled to the emitter electrode through the emitter contact hole,
when viewed in plan view, the emitter electrode and the emitter contact hole are elongated in a second direction perpendicular to the first direction,
a first condition is satisfied with respect to, of individual cells at two sides in the first direction among the cells, the at least one emitter electrode and the emitter contact hole surrounded by the emitter electrode when viewed in plan view; such that in the first condition, a length of the emitter contact hole is 85% or less of a length of the emitter electrode, and of two side ends of the emitter electrode, a distance from each side end to the emitter contact hole is 5% or more of the length of the emitter electrode, and
between two cells adjacent to each other in the first direction among the cells, one cell closer to an end in the first direction includes the emitter contact hole having a shortest length identical to or shorter than a shortest length of the emitter contact hole of another cell of the two cells.
